(19) United States
(12) Patent Application Publication
(10) Pub. No.: US 2026/0122899 A1
(43) Pub. Date: Apr. 30, 2026

(54) Integrated Circuitry And Method Used In Forming Integrated Circuitry

(71) Applicant: Micron Technology, Inc., Boise, ID (US)

(72) Inventors: David H. Wells, Boise, ID (US); Anna Maria Conti, Milano (IT); Maithilee Motlag, Boise, ID (US); Tyler L. List, Boise, ID (US); Rui Zhang, Boise, ID (US)

(73) Assignee: Micron Technology, Inc., Boise, ID (US)

(21) Appl. No.: 19/019,025

(22) Filed: Jan. 13, 2025

Related U.S. Application Data
(60) Provisional application No. 63/552,416, filed on Feb. 12, 2024.

(51) Int. Cl. H10B 43/35; H01L 23/522; H01L 23/528; H10B 43/10; H10B 43/20

(52) U.S. Cl. CPC H10B 43/35; H10B 43/10; H10B 43/20; H10W 20/42; H10W 20/43; H10W 20/435

(57) ABSTRACT

Integrated circuitry comprises a three-dimensional (3D) array region comprising tiers of electronic components and a stair-step region. The 3D array region comprises a stack comprising vertically-alternating insulative tiers and conductive tiers that extend into the stair-step region, the insulative tiers comprising insulative material. The stair-step region comprises a flight of stairs extending along a first direction. Multiple different-depth treads in individual of the stairs extend along a second direction that is orthogonal to the first direction. In the stair-step region, pluralities of first and second structures extend through the stack, the stairs, and the treads. The first structures are spaced along the first direction and comprise a radially-outermost first insulator material. The second structures are spaced along the first direction and comprise a radially-outermost second insulator material. A third insulator material extends elevationally between immediately-adjacent of the insulative tiers through the conductive tier there-between. The third insulator material is laterally between the first insulator material of the first structures and conducting material of individual of the conductive tiers. The third insulator material is of different composition from that of each of the insulative material, the first insulator material, and the second insulator material. The third insulator material is not laterally between the second insulator material of the second structures and the conducting material of the individual conductive tiers. Other embodiments, including method, are disclosed.

### TECHNICAL FIELD

Embodiments disclosed herein pertain to integrated circuitry and to methods used in forming integrated circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a z direction) comprising a three-dimensional (3D) memory array region having horizontal tiers in which individual memory cells are received (e.g., arrayed in x and y directions). The stack in the 3D memory array region comprises vertically-alternating insulative tiers and conductive tiers that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

Flash memory is one type of memory and has numerous uses in modern computers and devices. For instance, modern personal computers may have BIOS stored on a flash memory chip. As another example, it is becoming increasingly common for computers and other devices to utilize flash memory in solid state drives to replace conventional hard drives. As yet another example, flash memory is popular in wireless electronic devices because it enables manufacturers to support new communication protocols as they become standardized, and to provide the ability to remotely upgrade the devices for enhanced features.

NAND may be a basic architecture of integrated flash memory. A NAND cell unit comprises at least one selecting device coupled in series to a serial combination of memory cells (with the serial combination commonly being referred to as a NAND string). NAND architecture may be configured in a three-dimensional arrangement comprising vertically-stacked memory cells individually comprising a reversibly programmable vertical transistor. Control or other circuitry may be formed below the vertically-stacked memory cells. Other volatile or non-volatile memory array architectures may also comprise vertically-stacked memory cells that individually comprise a transistor.

The inventions herein were primarily motivated in challenges associated with the fabrication and final construction of memory circuitry, particularly NAND flash memory. However, the invention has applicability to any fabrication and/or any structure having a 3D array region comprising tiers of electronic components and a stair-step region where the 3D array region comprises vertically-alternating insulative tiers and conductive tiers that extend into the stair-step region.

### BRIEF DESCRIPTION OF THE DRAWINGS

FIGS. 1-6 are diagrammatic cross-sectional views of portions of a construction that will comprise circuitry in accordance with an embodiment of the invention.

FIGS. 7-22 are diagrammatic sequential sectional and/or enlarged views of the construction of FIGS. 1-3, or portions thereof or alternate and/or additional embodiments, in process in accordance with some embodiments of the invention.

### DETAILED DESCRIPTION OF EXAMPLE EMBODIMENTS

Embodiments of the invention encompass methods used in forming integrated circuitry, for example a three-dimensional (3D) array comprising tiers of electronic components. Those electronic components may act as a single circuit component (e.g., a non-volatile and programmable charge-storage transistor of a vertical NAND string) or may combine with another electronic component or components to form a single circuit component (e.g., one capacitor and one transistor that in combination form a single circuit component in the form of one DRAM cell). Other memory as well as non-memory applications and electronic components are contemplated (e.g., diodes, resistors, inductors, fuses, amplifiers, etc.).

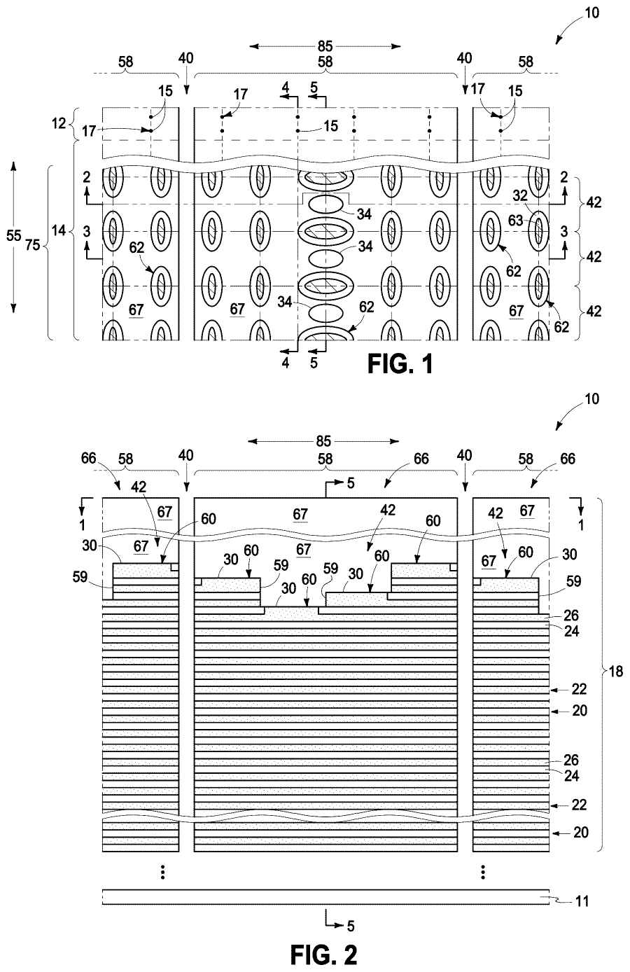

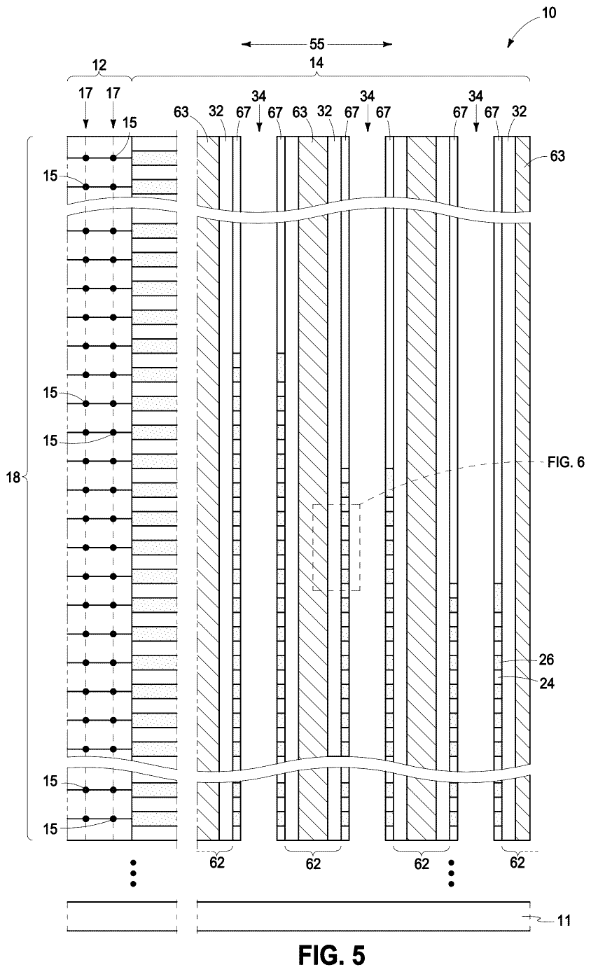

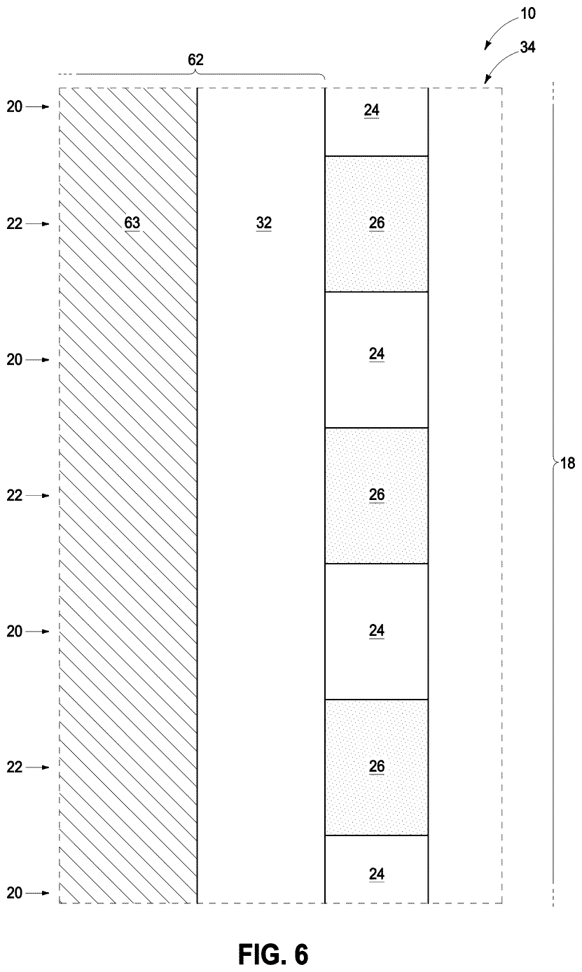

FIGS. 1-6 show an example construction 10 in a process of manufacture in accordance with method embodiments of the invention. Construction 10 has a base substrate 11 that may have any combination of conductive/conductor/conducting, semiconductive/semiconductor/semiconducting, or insulative/insulator/insulating (i.e., electrically herein) materials. Various materials have been formed directly above base substrate 11. Materials may be aside, elevationally inward, or elevationally outward of the FIGS. 1-6-depicted materials. For example, other partially or wholly fabricated components of integrated circuitry may be provided somewhere above, about, or within base substrate 11.

A stack 18 has been formed above base substrate 11. Such comprises vertically-alternating sacrificial-material tiers 22 and insulative tiers 20 that extend from a three-dimensional (3D) array region 12 into a stair-step region 14. Sacrificial-material tiers 22 are conductive in a finished-circuitry construction, may or may not be so at this point of processing, and in some embodiments are referred to as conductive tiers 22. Example thickness for each of tiers 20 and 22 is 20 to 60 nanometers, and such may be of different thicknesses relative one another including, for example, multiple different thickness insulative tiers and multiple different thickness sacrificial-material tiers. Example sacrificial-material tiers 22 are shown as comprising sacrificial material 26 (e.g., silicon nitride or polysilicon) and example insulative tiers 20 are shown as comprising insulative material 24 (of different etchable-composition from that of material 26; e.g., silicon dioxide). Only a small number of tiers 20 and 22 is shown in FIGS. 1-6 and other figures, with more likely stack 18 comprising dozens, a hundred or more, etc. of tiers 20 and 22.

3D array region 12 comprises tiers of electronic components 15 in the finished-circuitry construction which may or may not exist at this point of processing. Example electronic components 15 are by way of example only shown schematically, in two columns, and which electrically couple (e.g., directly electrically couple) with conductive material (not yet shown) of individual conductive tiers 22. In one embodiment, the integrated circuitry being fabricated and resulting comprises NAND memory and the electronic components comprise memory cells of individual vertical NAND strings 17. Likely many more electronic components 15 would be within 3D array region 12, with 3D array region 12 likely being considerably larger than stair-step region 14.

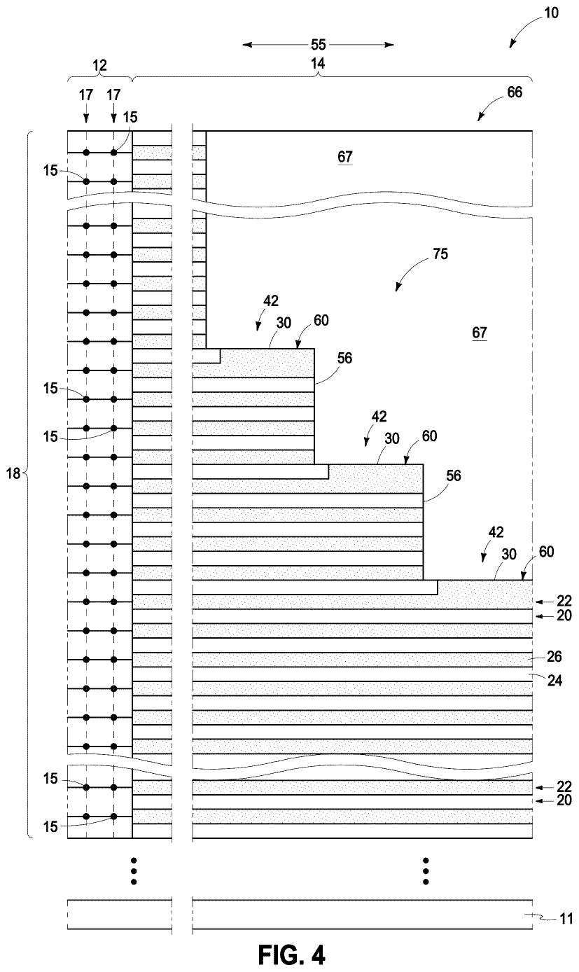

Stair-step region 14 comprises a flight 75 of stairs 42 extending along a first direction 55 and, for example, that has been formed in a cavity 66. Construction 10 may be considered as comprising stair risers 56 between immediately-adjacent stairs 42. In this document, “immediately-adjacent” refers to two like features that do not have any other such like feature there-between. Only three stairs 42 are shown in flight 75 and two or more than three such stairs (not shown) may be used. Cavity 66 may include a mirror-image to the right in FIG. 4 of analogous stairs going from down to up (e.g., left-to-right, and not shown). Example cavity 66 has been filled with insulating material 67 (e.g., silicon dioxide). Multiple cavities 66 (not shown) would likely be included in stair-step region 14 and that individually comprise flights of stairs to different elevation conductive tiers 22.

Trenches 40 have been formed through stack 18 and extend from 3D array region 12 into stair-step region 14 along first direction 55. Trenches 40 are spaced along a second direction 85 that is orthogonal to first direction 55 and divide flight 75 of stairs 42 into sections 58 that are spaced along second direction 85 (e.g., memory blocks 58 in NAND). Individual of stairs 42 in individual of sections 58 comprise multiple different-depth treads 30 extending along second direction 85. Construction 10 may be considered as comprising tread risers 59 between immediately-adjacent treads 30. Stairs 42 and treads 30 may be constructed as shown by any suitable manner(s), for example using a plurality of etching steps that etch at least two of tiers 20, 22 alternating with lateral-trimming steps that widen masking-material openings to progressively form stairs and/or treads into the stack. Sacrificial spacers (not shown) may alternately or additionally be used.

Regardless, in one embodiment and as shown, sacrificial material 26 in individual treads 30 projects upwardly from sacrificial material 26 of a highest of sacrificial-material tiers 22 of said individual tread 30 to comprise a sacrificial-material mesa 60. Such mesas may be formed in any manner. As an example, where sacrificial material 26 comprises silicon nitride, tier silicon nitride 26 of treads 30 could be etched laterally-back slightly, followed by anisotropically etching away tier silicon dioxide 24 that is atop the treads. More silicon nitride 26 could then be deposited to contact the now-exposed silicon nitride of the treads and to line the risers and the treads to the desired vertical thickness of the mesas. Such deposited silicon nitride could then be subjected to a vertically-directional nitrogen-containing plasma that adds nitrogen to the silicon nitride and/or densifies it. The remaining original of such deposited nitride could then be etched selectively relative to the plasma-treated nitride, leaving sacrificial-material mesas 60 behind.

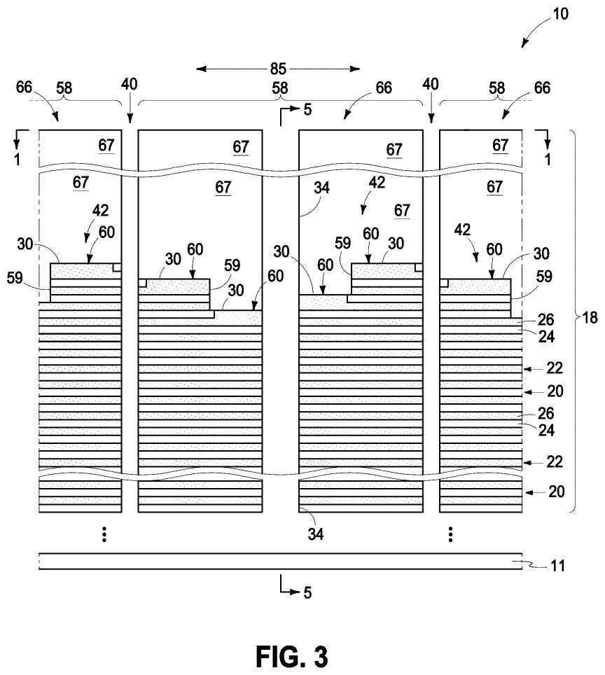

Openings 34 have been formed to extend through stack 18 in stair-step region 14. Openings 34 are spaced along first direction 55 between immediately-adjacent trenches 40. In one embodiment and as shown, openings 34 are spaced along a horizontal straight line there-through (e.g., section line 5-5) that is parallel first direction 55 and in one such embodiment as shown with such straight line being centered in second direction 85 between immediately-adjacent trenches 40. In one embodiment, openings 34 are individually spaced in first direction 55 from immediately-adjacent stair risers 56. In one embodiment, openings 34 individually extend through one of tread risers 59 (e.g., as shown when comparing FIGS. 2 and 3). Openings 34 could be formed before, after, or simultaneously with the forming of trenches 40.

In some embodiments, first structures 62 have been formed and that extend though stack 18, stairs 42, and treads 30. First structures 62 are spaced along first direction 55 (e.g., and in second direction 85) and comprise a radially-outermost first insulator material 32. Example first structures 62 comprise a core 63 which, in one embodiment, is conductive and in one such embodiment with first structures 62 comprising live or dummy through-array-vias. First structures 62 may be formed before or after forming one or both of openings 34 or trenches 40.

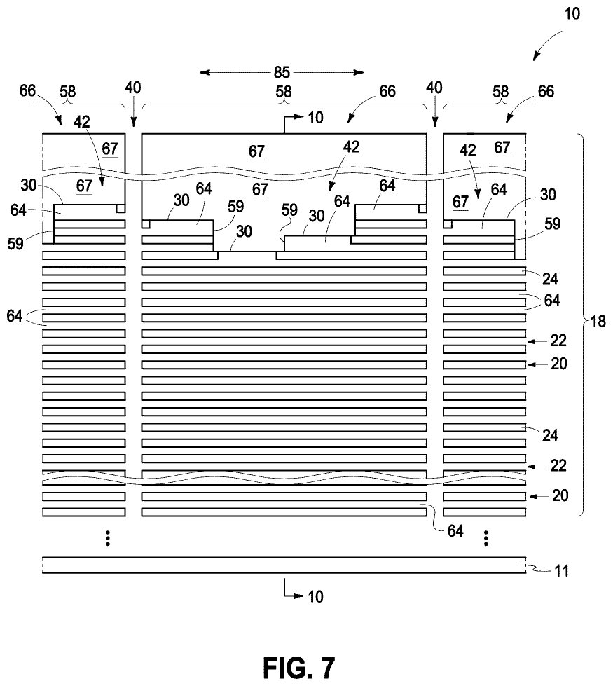

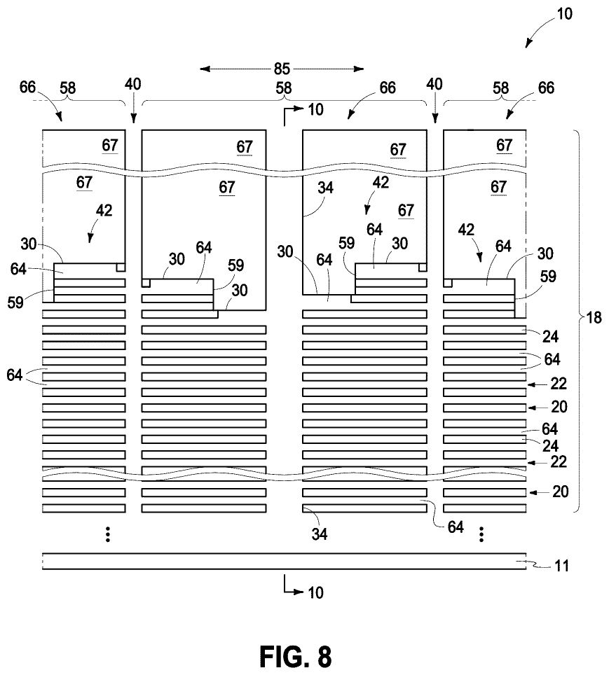

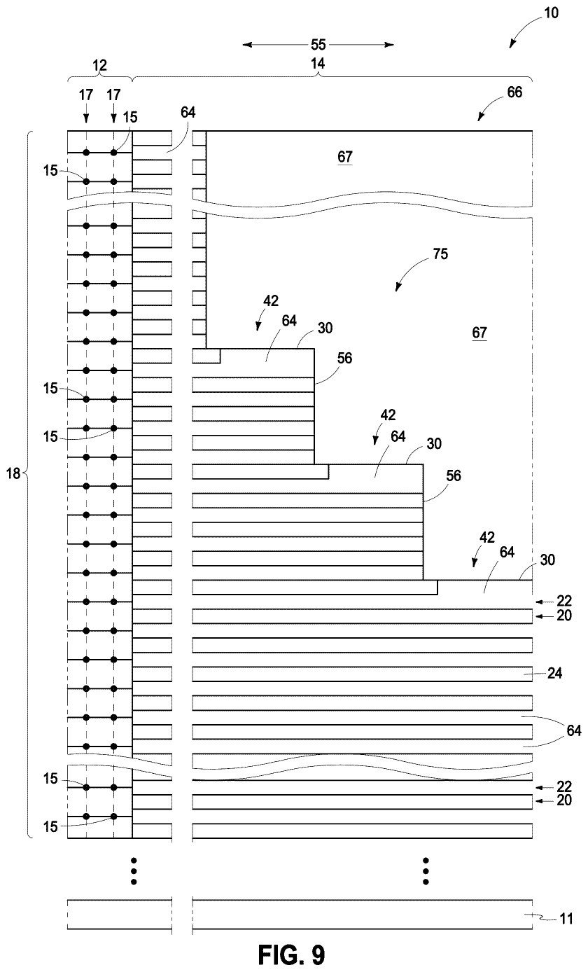

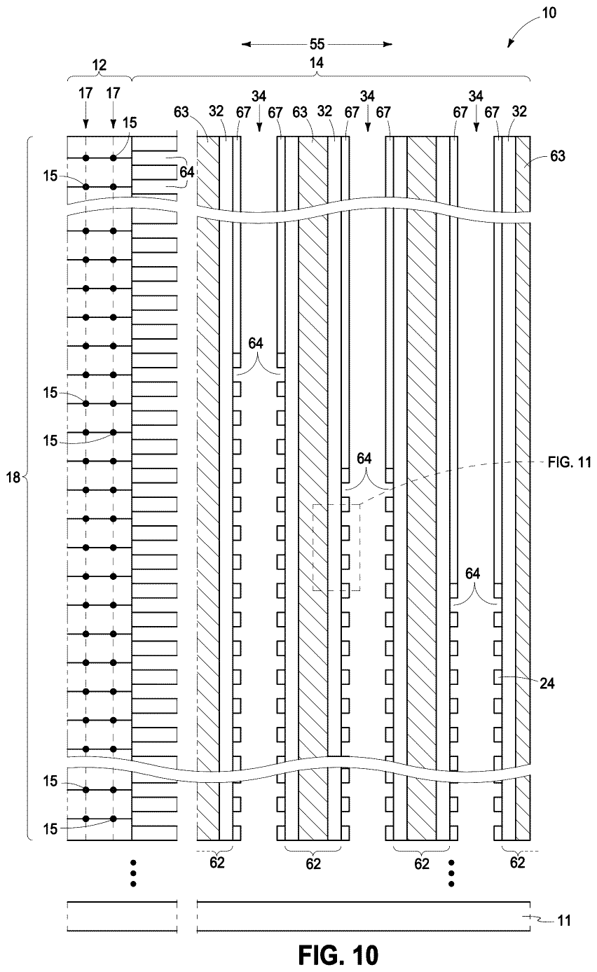

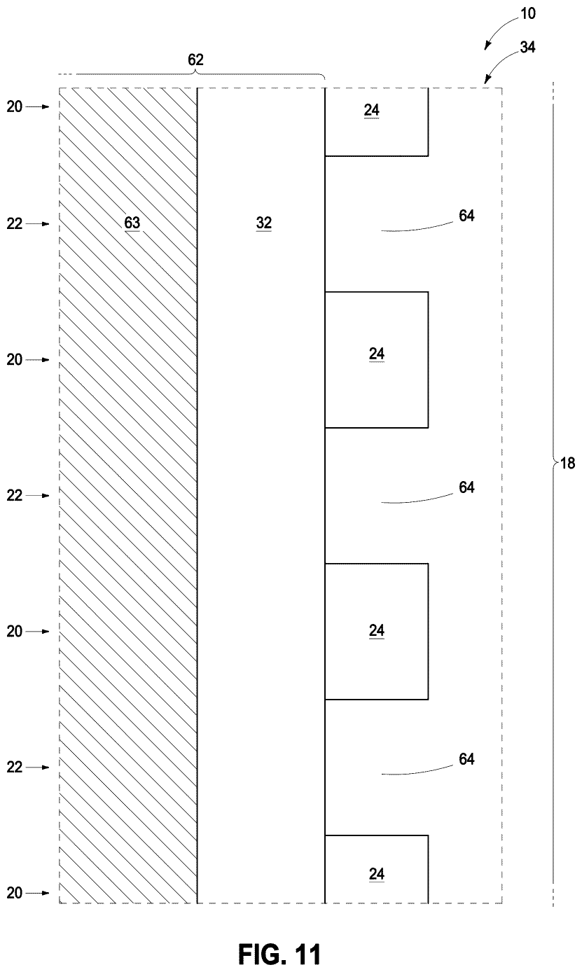

Referring to FIGS. 7-11, an etchant has simultaneously been flowed through trenches 40 and openings 34 and sacrificial material 26 has been etched therewith (at least some, all as shown, with material 26 thereby not being shown) selectively relative to insulative material 24 to form void space 64 between immediately-adjacent insulative tiers 20 (e.g., H₃PO₄ being an example etchant for Si₃N₄ and tetramethyl-ammonium hydroxide being an example etchant for polysilicon where insulative material 24 is silicon dioxide). In one embodiment where sacrificial-material mesas 60 are present as shown in FIGS. 2-5, such are also etched to remove such (sacrificial-material mesas 60 thereby not being shown in FIGS. 7-10).

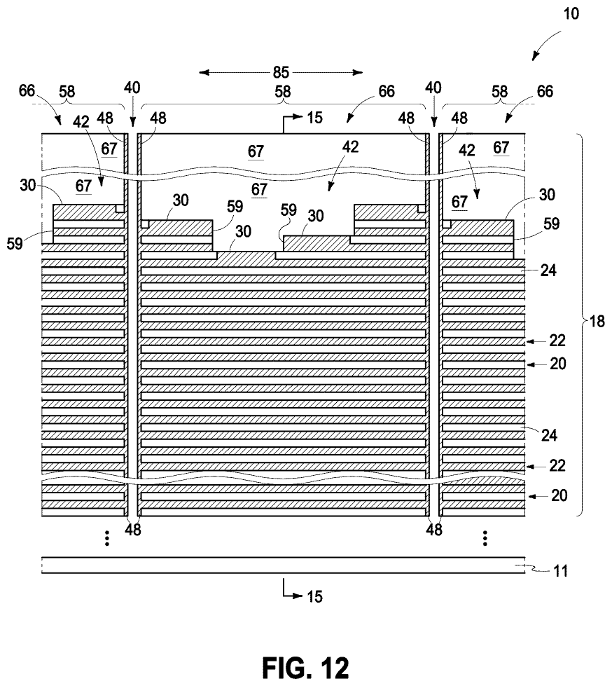

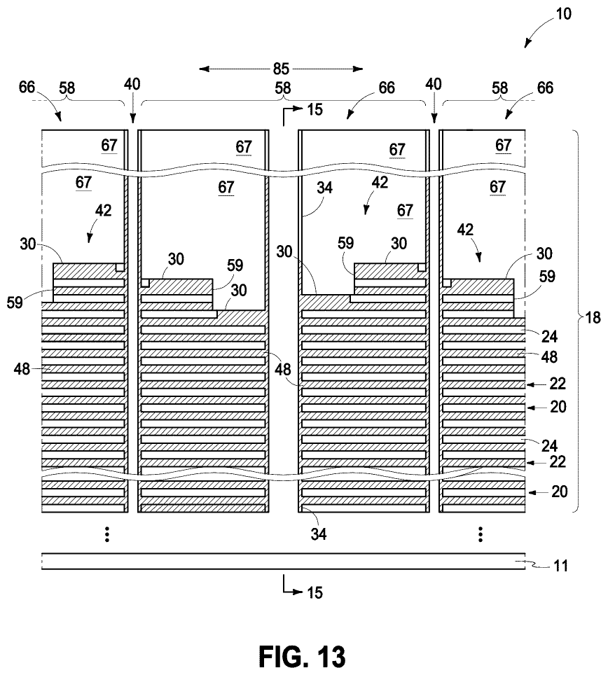

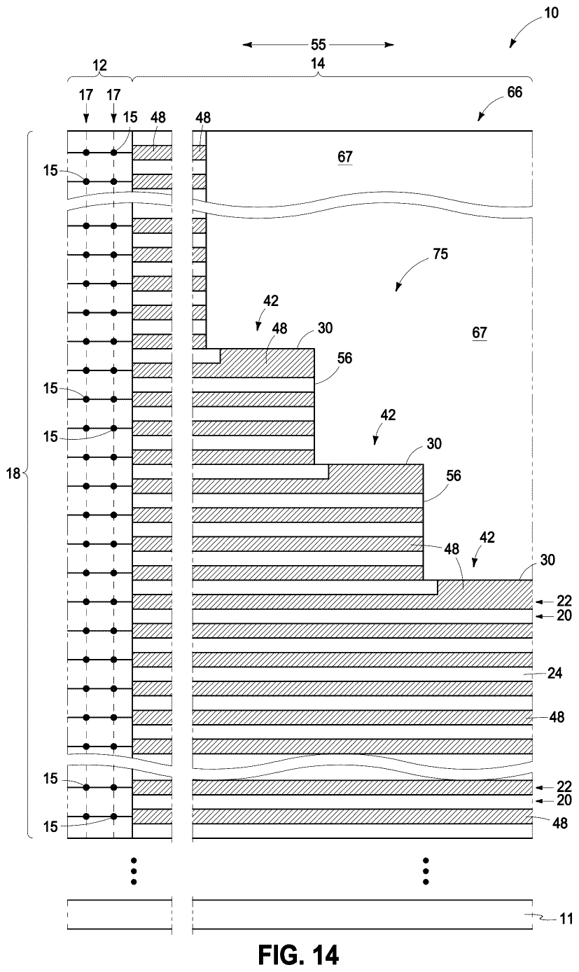

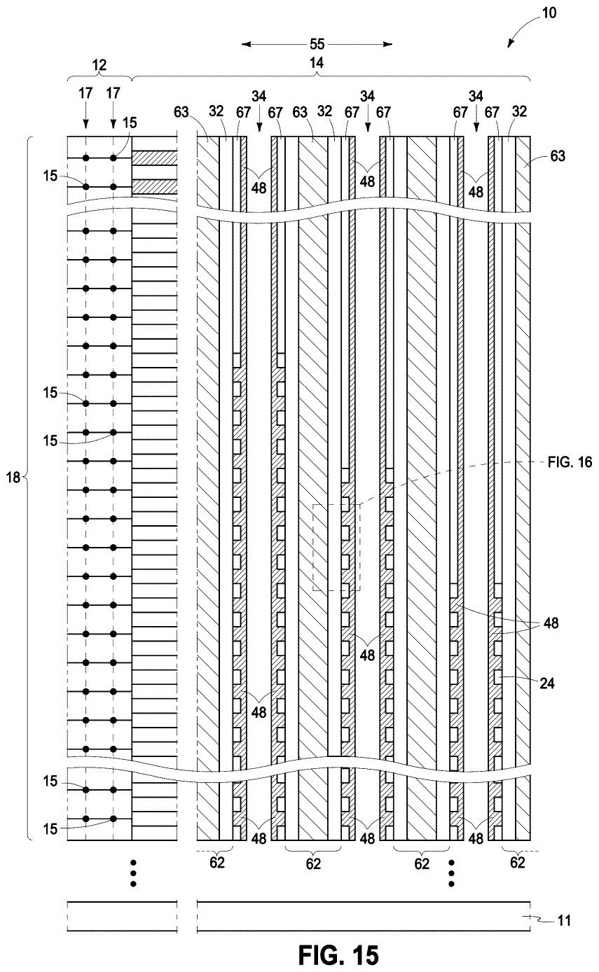

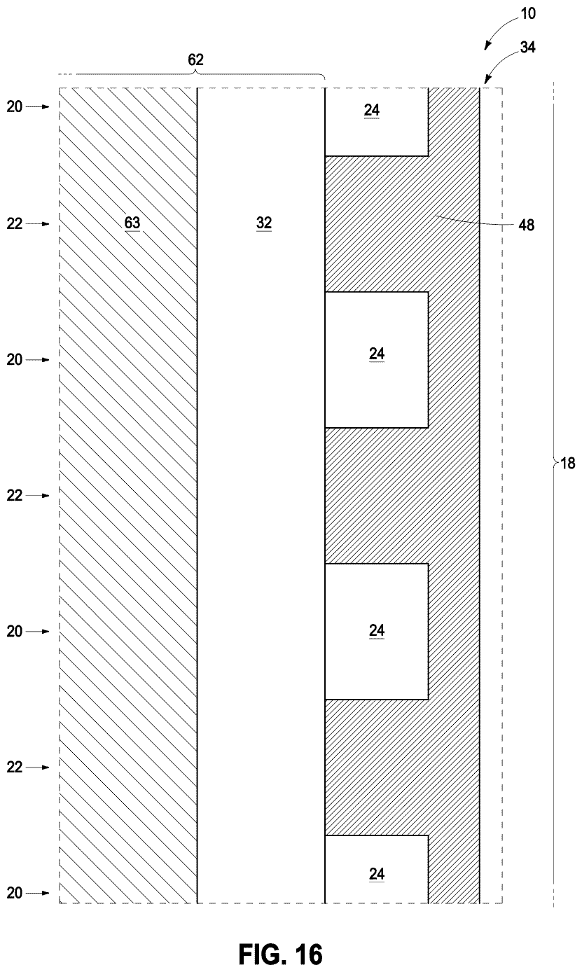

Referring to FIGS. 12-16, void space 64 (no longer shown) has been filled (at least partially) with conducting material 48 by simultaneously flowing conducting material 48 or one or more precursors thereof through openings 34 and trenches 40 to into such void space. In one embodiment where there was a sacrificial-material mesa 60 that was removed in FIGS. 7-11, such filling forms a conductive mesa 68 that contacts and projects upwardly from conducting material 48 of the highest conductive tier 22 of individual treads 30. In one embodiment and as shown, the filling forms conducting material 48 elevationally along insulative tiers 20 within individual openings 34 and trenches 40.

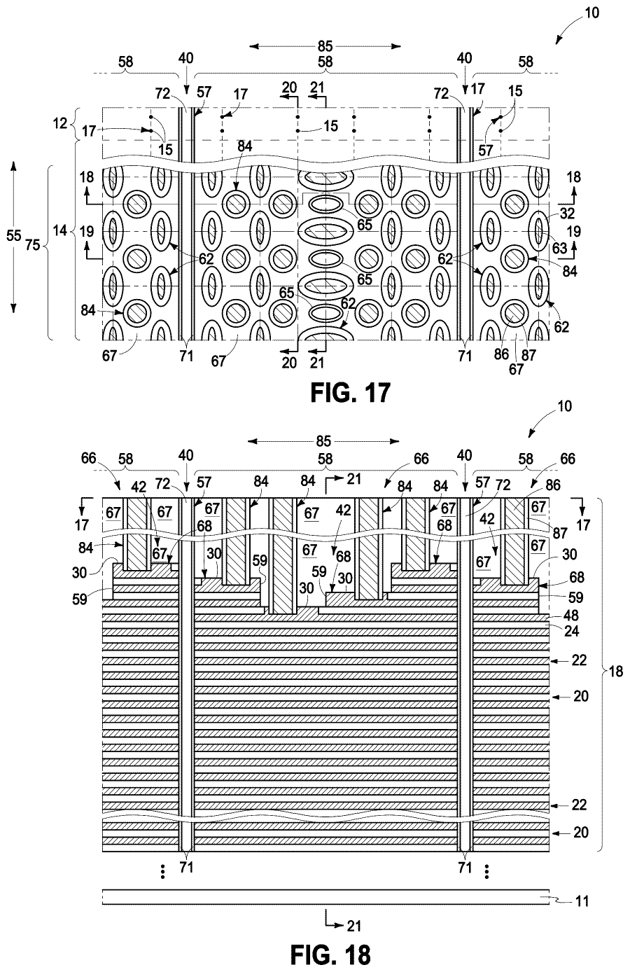

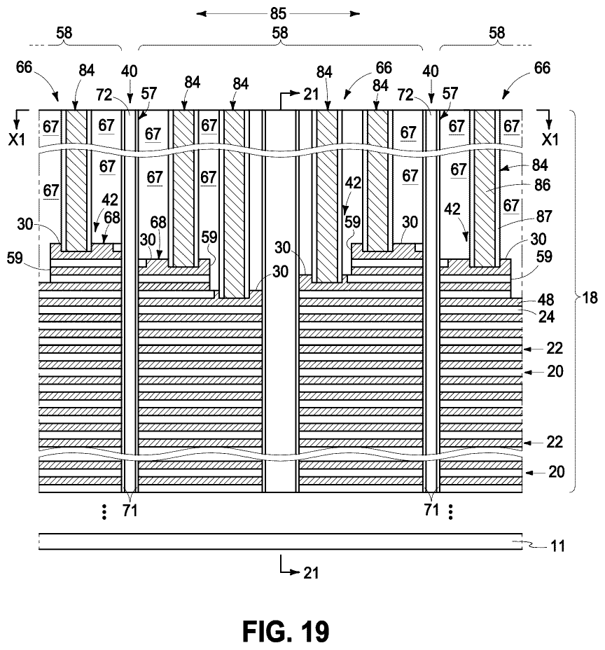

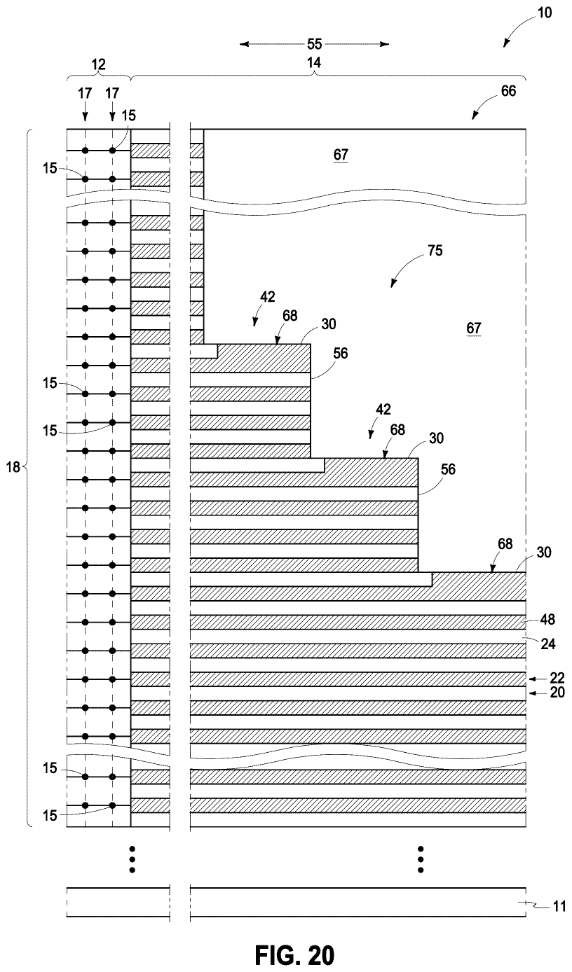

FIGS. 17-22, show removing (e.g., by etching) conducting material 48 from being elevationally along insulative tiers 20 within individual openings 34 and trenches 40, followed by simultaneously filling (at least partially) trenches 40 and openings 34 with a same solid material 57, in some embodiments. Material within openings 34 and trenches 40 may be porous and/or include void space (neither being shown). In one embodiment, material 57 comprises radially-outermost second insulator material 71 (e.g., silicon dioxide and/or silicon nitride) and core material 72 (e.g., an insulator or polysilicon). Example conductive via constructions 84 (e.g., comprising a conductive metal core 86 with insulative outer cylinder 87) directly electrically couple to individual treads 30. In one embodiment including conductive mesas 68, conductive via constructions 84 individually directly electrically couple with and extend upwardly from individual conductive mesas 68, with individual conductive via constructions 84 being of smaller horizontal cross-section than that of conductive mesa 68 where individual conductive mesas 68 and conductive via constructions 84 join with one another.

In some embodiments, the material formed in openings 34 may be considered as forming second structures 65 that extend though stack 18, stairs 42, and treads 30, with second structures 65 being spaced along first direction 55 and comprising a radially-outermost second insulator material 71 (regardless of presence of a different composition material radially-inward thereof).

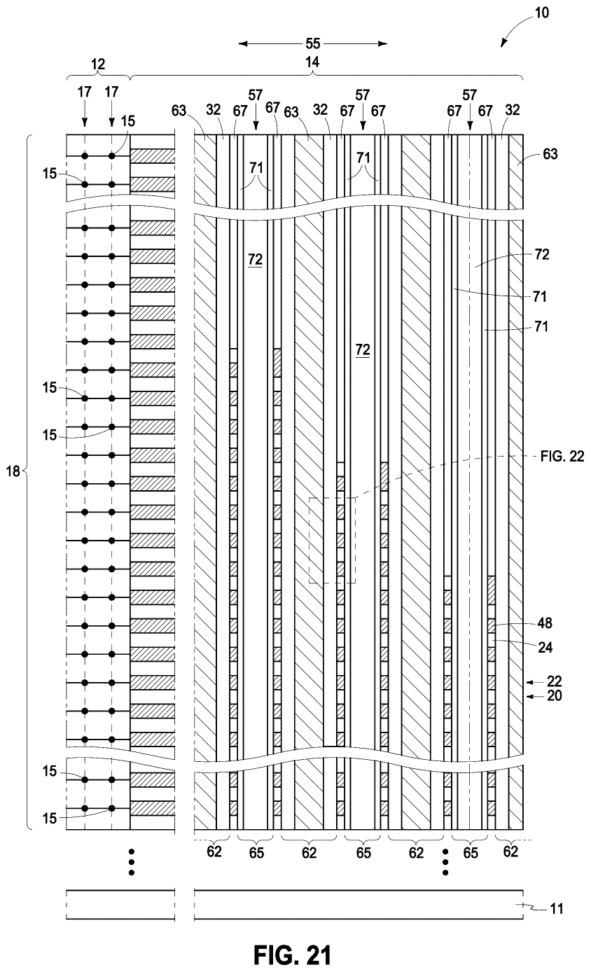

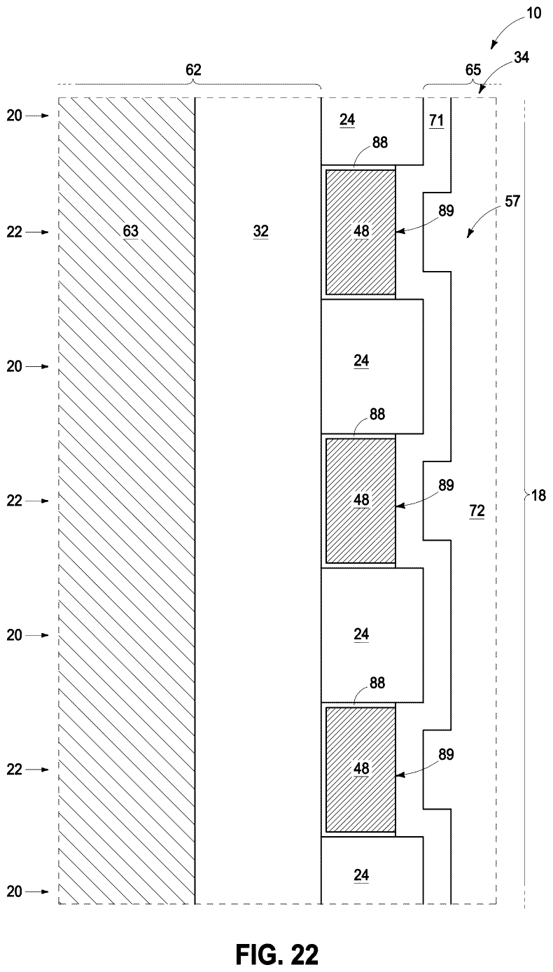

Referring to FIG. 22 (an enlargement of a portion of FIG. 21) and in one embodiment, a third insulator material 88 extends elevationally between immediately-adjacent insulative tiers 20 through the conductive tier 22 that is there-between. Third insulator material 88 is laterally between first insulator material 32 of first structures 62 and conducting material 48 of individual conductive tiers 22. Third insulator material 88 is of different composition (e.g., AlOₓ, HfOₓ, SiOₓ, SiNₓ) from that of each of insulative material 24, first insulator material 32, and second insulator material 71. In one embodiment and as shown, third insulator material 88 is not laterally between second insulator material 71 of second structures 65 and conducting material 48 of individual conductive tiers 22. In one embodiment and as shown, second insulator material 71 of second structures 65 is directly against a sidewall 89 of conducting material 48 of individual conductive tiers 22. Materials 88 and 48 may be laterally recessed (as shown) relative to sidewalls of openings 34 prior to forming material 57, whereby material 57 (e.g., at least second insulator material 71 thereof) extends into the lateral/radial recesses formed thereby.

Any other attribute(s) or aspect(s) as shown and/or described herein with respect to other embodiments may be used in the embodiments shown and described with reference to the above embodiments.

Alternate embodiment constructions may result from method embodiments described above, or otherwise. Regardless, embodiments of the invention encompass circuitry independent of method of manufacture. Nevertheless, such circuitry arrays may have any of the attributes as described herein in method embodiments. Likewise, the above-described method embodiments may incorporate, form, and/or have any of the attributes described with respect to device embodiments.

In some embodiments, integrated circuitry (e.g., 10) comprises a three-dimensional (3D) array region (e.g., 12) comprising tiers of electronic components (e.g., 15) and a stair-step region (e.g., 14). The 3D array region comprises a stack (e.g., 18) comprising vertically-alternating insulative tiers (e.g., 20) and conductive tiers (e.g., 22) that extend into the stair-step region. The insulative tiers comprise insulative material (e.g., 24). The stair-step region comprises a flight (e.g., 75) of stairs (e.g., 42) extending along a first direction (e.g., 55). Multiple different-depth treads (e.g., 30) in individual of the stairs extend along a second direction (e.g., 85) that is orthogonal to the first direction. Pluralities of first (e.g., 62) and second (e.g., 65) structures are in the stair-step region and extend though the stack, the stairs, and the treads. The first structures are spaced along the first direction and comprise a radially-outermost first insulator material (e.g., 32). The second structures are spaced along the first direction and comprise a radially-outermost second insulator material (e.g., 71). A third insulator material (e.g., 88) extends elevationally between immediately-adjacent of the insulative tiers through the conductive tier there-between. The third insulator material is laterally between the first insulator material of the first structures and conducting material (e.g., 48) of individual of the conductive tiers. The third insulator material is of different composition from that of each of the insulative material, the first insulator material, and the second insulator material. The third insulator material is not laterally between the second insulator material of the second structures and the conducting material of the individual conductive tiers.

In one embodiment, the third insulator material is directly above and directly below the conducting material of the individual conductive tiers and is directly against the third insulator material that extends elevationally between immediately-adjacent of the insulative tiers. In one embodiment, the second structures are spaced along a horizontal straight line there-through (e.g., the section line 21-21) that is parallel the first direction. In one such latter embodiment, walls (e.g., comprising material 57 in trenches 40) extend through the stack and from the 3D array region into the stair-step region along the first direction, with the walls being spaced along the second direction and dividing the flight of stairs into sections (e.g., 58) that are spaced along the second direction. Individual of the sections comprise a plurality of the different-depth treads that extend along the second direction in the individual stairs. In one embodiment, the straight line (e.g., section line 21-21) is centered in the second direction between immediately-adjacent of the walls.

In one embodiment, the walls individually comprise two opposing laterally-outermost layers of the second insulator material (e.g., 71), with the walls and second structures individually comprising a core (e.g., 72) comprising one or more solid materials that are common in the walls and second structures. In one embodiment, a stair riser (e.g., 56) is between immediately-adjacent of the stairs, with the second structures being individually spaced in the first direction from immediately-adjacent of the stair risers. In one embodiment, a tread riser (e.g., 59) is between immediately-adjacent of the treads, with the second structures individually extending through one of the tread risers. In one embodiment, individual of the treads comprise a conductive mesa (e.g., 68) that contacts and projects upwardly from conductive material of a highest of the conductive tiers of said individual tread. A conductive via construction (e.g., 84) directly electrically couples with and extends upwardly from the conductive mesa, with the conductive via construction being of smaller horizontal cross-section than that of the conductive mesa where the conductive mesa and the conductive via construction join with one another.

Any other attribute(s) or aspect(s) as shown and/or described herein with respect to other embodiments may be used.

In some embodiments, integrated circuitry (e.g., 10) comprises a three-dimensional (3D) array region (e.g., 12) comprising tiers of electronic components (e.g., 15) and a stair-step region (e.g., 14). The 3D array region comprises a stack (e.g., 18) comprising vertically-alternating insulative tiers (e.g., 20) and conductive tiers (e.g., 22) that extend into the stair-step region. The insulative tiers comprise insulative material (e.g., 24). The stair-step region comprises a flight (e.g., 75) of stairs (e.g., 42) extending along a first direction (e.g., 55). Multiple different-depth treads (e.g., 30) in individual of the stairs extend along a second direction (e.g., 85) that is orthogonal to the first direction. Pluralities of first (e.g., 62) and second (e.g., 65) structures are in the stair-step region and extend though the stack, the stairs, and the treads. The first structures are spaced along the first direction and comprise a radially-outermost first insulator material (e.g., 32). The second structures are spaced along the first direction and comprise a radially-outermost second insulator material (e.g., 71). A third insulator material (e.g., 88) extends elevationally between immediately-adjacent of the insulative tiers through the conductive tier there-between. The third insulator material is laterally between the first insulator material of the first structures and conducting material (e.g., 48) of individual of the conductive tiers. The third insulator material is of different composition from that of each of the insulative material, the first insulator material, and the second insulator material. The second insulator material of the second structures is directly against a sidewall (e.g., 89) of the conducting material of the individual conductive tiers. Any other attribute(s) or aspect(s) as shown and/or described herein with respect to other embodiments may be used.

Heretofore, it has been difficult to get etchant in replacement-gate processing solely from trenches 40 to etch all the sacrificial material from tiers 22. This is particularly true when there are more than two treads per stair and/or when using sacrificial-material mesas 60. Method aspects of the invention may overcome or reduce such problems, although the inventions disclosed herein and in no way so limited.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend (ing) elevationally” “elevationally-extending”, “extend (ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method used in forming integrated circuitry comprises forming a stack comprising vertically-alternating sacrificial-material tiers and insulative tiers that extend from a three-dimensional (3D) array region into a stair-step region. The 3D array region comprises tiers of electronic components in a finished-circuitry construction. The stair-step region comprises a flight of stairs extending along a first direction. Trenches are formed through the stack that extend from the 3D array region into the stair-step region along the first direction. The trenches are spaced along a second direction that is orthogonal to the first direction and divides the flight of stairs into sections that are spaced along the second direction. Individual of the stairs in individual of the sections comprise multiple different-depth treads extending along the second direction. Openings are formed that extend through the stack in the stair-step region. The openings are spaced along the first direction between immediately-adjacent of the trenches. An etchant is simultaneously flowed through the trenches and the openings and the sacrificial material is etched therewith selectively relative to the insulative material to form void space between immediately-adjacent of the insulative tiers. The void space is filled with conducting material by simultaneously flowing the conducting material or one or more precursors thereof through the openings and the trenches to into the void space.

In some embodiments, integrated circuitry comprising a three-dimensional (3D) array region comprises tiers of electronic components and a stair-step region. The 3D array region comprises a stack comprising vertically-alternating insulative tiers and conductive tiers that extend into the stair-step region. The insulative tiers comprise insulative material. The stair-step region comprises a flight of stairs extending along a first direction. Multiple different-depth treads in individual of the stairs extend along a second direction that is orthogonal to the first direction. In the stair-step region, pluralities of first and second structures extend though the stack, the stairs, and the treads. The first structures are spaced along the first direction and comprise a radially-outermost first insulator material. The second structures are spaced along the first direction and comprise a radially-outermost second insulator material. A third insulator material extends elevationally between immediately-adjacent of the insulative tiers through the conductive tier there-between. The third insulator material is laterally between the first insulator material of the first structures and conducting material of individual of the conductive tiers. The third insulator material is of different composition from that of each of the insulative material, the first insulator material, and the second insulator material. The third insulator material is not laterally between the second insulator material of the second structures and the conducting material of the individual conductive tiers.

In some embodiments, integrated circuitry comprising a three-dimensional (3D) array region comprises tiers of electronic components and a stair-step region. The 3D array region comprises a stack comprising vertically-alternating insulative tiers and conductive tiers that extend into the stair-step region. The insulative tiers comprise insulative material. The stair-step region comprises a flight of stairs extending along a first direction. Multiple different-depth treads in individual of the stairs extend along a second direction that is orthogonal to the first direction. In the stair-step region, pluralities of first and second structures extend though the stack, the stairs, and the treads. The first structures are spaced along the first direction and comprise a radially-outermost first insulator material. The second structures are spaced along the first direction and comprise a radially-outermost second insulator material. A third insulator material extends elevationally between immediately-adjacent of the insulative tiers through the conductive tier there-between. The third insulator material is laterally between the first insulator material of the first structures and conducting material of individual of the conductive tiers. The third insulator material is of different composition from that of each of the insulative material, the first insulator material, and the second insulator material. The second insulator material of the second structures is directly against a sidewall of the conducting material of the individual conductive tiers.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming integrated circuitry, comprising:
forming a stack comprising vertically-alternating sacrificial-material tiers and insulative tiers that extend from a three-dimensional (3D) array region into a stair-step region, the 3D array region comprising tiers of electronic components in a finished-circuitry construction, the stair-step region comprising a flight of stairs extending along a first direction;
forming trenches through the stack that extend from the 3D array region into the stair-step region along the first direction, the trenches being spaced along a second direction that is orthogonal to the first direction and dividing the flight of stairs into sections that are spaced along the second direction, individual of the stairs in individual of the sections comprising multiple different-depth treads extending along the second direction;
forming openings that extend through the stack in the stair-step region, the openings being spaced along the first direction between immediately-adjacent of the trenches;
simultaneously flowing an etchant through the trenches and the openings and etching therewith the sacrificial material selectively relative to the insulative material to form void space between immediately-adjacent of the insulative tiers; and
filling the void space with conducting material by simultaneously flowing the conducting material or one or more precursors thereof through the openings and the trenches to into the void space.

2. The method of claim 1 wherein the filling forms the conducting material elevationally along the insulative tiers within individual of the openings and the trenches; and
after the filling, removing the conducting material from being elevationally along the insulative tiers within individual of the openings and the trenches.

3. The method of claim 1 comprising, after the filling, simultaneously filling (at least partially) the trenches and the openings with a same solid material.

4. The method of claim 1 wherein the openings are spaced along a horizontal straight line there-through that is parallel the first direction.

5. The method of claim 4 wherein the straight line is centered in the second direction between immediately-adjacent of the trenches.

6. The method of claim 1 comprising a stair riser between immediately-adjacent of the stairs, the openings being individually spaced in the first direction from immediately-adjacent of the stair risers.

7. The method of claim 1 comprising a tread riser between immediately-adjacent of the treads, the openings individually extending through one of the tread risers.

8. The method of claim 7 comprising a stair riser between immediately-adjacent of the stairs, the openings being individually spaced in the first direction from immediately-adjacent of the stair risers.

9. The method of claim 1 wherein,
the sacrificial material in individual of the treads projects upwardly from the sacrificial material of a highest of the sacrificial-material tiers of said individual tread to comprise a sacrificial-material mesa;
the etching removes the sacrificial-material mesa; and
the filling forms a conductive mesa that contacts and projects upwardly from conductive material of a highest of the conductive tiers of said individual tread.

10. The method of claim 9 comprising forming a conductive via construction that directly electrically couples with and extends upwardly from the conductive mesa, the conductive via construction being of smaller horizontal cross-section than that of the conductive mesa where the conductive mesa and the conductive via construction join with one another.

11. The method of claim 1 wherein the integrated circuitry comprises NAND memory and the electronic components comprise memory cells of individual vertical NAND strings.

12. Integrated circuitry comprising:
a three-dimensional (3D) array region comprising tiers of electronic components and a stair-step region, the 3D array region comprising a stack comprising vertically-alternating insulative tiers and conductive tiers that extend into the stair-step region, the insulative tiers comprising insulative material;
the stair-step region comprising a flight of stairs extending along a first direction, multiple different-depth treads in individual of the stairs extending along a second direction that is orthogonal to the first direction;
in the stair-step region, pluralities of first and second structures that extend through the stack, the stairs, and the treads; the first structures being spaced along the first direction and comprising a radially-outermost first insulator material, the second structures being spaced along the first direction and comprising a radially-outermost second insulator material; and
a third insulator material extending elevationally between immediately-adjacent of the insulative tiers through the conductive tier there-between; the third insulator material being laterally between the first insulator material of the first structures and conducting material of individual of the conductive tiers; the third insulator material being of different composition from that of each of the insulative material, the first insulator material, and the second insulator material; the third insulator material not being laterally between the second insulator material of the second structures and the conducting material of the individual conductive tiers.

13. The integrated circuitry of claim 12 wherein the second insulator material of the second structures is directly against a sidewall of the conducting material of the individual conductive tiers.

14. The integrated circuitry of claim 12 wherein the third insulator material is directly above and directly below the conducting material of the individual conductive tiers and is directly against the third insulator material that extends elevationally between immediately-adjacent of the insulative tiers.

15. The integrated circuitry of claim 12 wherein the second structures are spaced along a horizontal straight line there-through that is parallel the first direction.

16. The integrated circuitry of claim 15 comprising walls that extend through the stack and from the 3D array region into the stair-step region along the first direction, the walls being spaced along the second direction and dividing the flight of stairs into sections that are spaced along the second direction, individual of the sections comprising a plurality of the different-depth treads that extend along the second direction in the individual stairs, the straight line being centered in the second direction between immediately-adjacent of the walls.

17. The integrated circuitry of claim 12 comprising walls that extend through the stack and from the 3D array region into the stair-step region along the first direction, the walls being spaced along the second direction and dividing the flight of stairs into sections that are spaced along the second direction, individual of the sections comprising a plurality of the different-depth treads that extend along the second direction in the individual stairs, the walls individually comprising two opposing laterally-outermost layers of the second insulator material, the walls and second structures individually comprising a core comprising one or more solid materials that are common in the walls and second structures.

18. The integrated circuitry of claim 12 comprising a stair riser between immediately-adjacent of the stairs, the second structures being individually spaced in the first direction from immediately-adjacent of the stair risers.

19. The integrated circuitry of claim 12 comprising a tread riser between immediately-adjacent of the treads, the second structures individually extending through one of the tread risers.

20. Integrated circuitry comprising:
a three-dimensional (3D) array region comprising tiers of electronic components and a stair-step region, the 3D array region comprising a stack comprising vertically-alternating insulative tiers and conductive tiers that extend into the stair-step region, the insulative tiers comprising insulative material;
the stair-step region comprising a flight of stairs extending along a first direction, multiple different-depth treads in individual of the stairs extending along a second direction that is orthogonal to the first direction;
in the stair-step region, pluralities of first and second structures that extend through the stack, the stairs, and the treads; the first structures being spaced along the first direction and comprising a radially-outermost first insulator material, the second structures being spaced along the first direction and comprising a radially-outermost second insulator material; and
a third insulator material extending elevationally between immediately-adjacent of the insulative tiers through the conductive tier there-between; the third insulator material being laterally between the first insulator material of the first structures and conducting material of individual of the conductive tiers; the third insulator material being of different composition from that of each of the insulative material, the first insulator material, and the second insulator material; the second insulator material of the second structures being directly against a sidewall of the conducting material of the individual conductive tiers.
